(19) United States
(12) Patent Application Publication
(10) Pub. No.: US 2009/0109639 A1
(43) Pub. Date: Apr. 30, 2009

(54) PORTABLE ELECTRONIC DEVICE AND METHOD FOR IDENTIFYING ACCESSORY CONNECTED TO THE SAME

(75) Inventor: CHIH-HAO LI, Tu-Cheng (TW)

Correspondence Address: PCE INDUSTRY, INC.;ATT. Steven Reiss, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 11/964,780

(22) Filed: Dec. 27, 2007

(30) Foreign Application Priority Data
Oct. 29, 2007 (CN) 200710202296.5

(51) Int. Cl. H05K 1/00; G01R 31/02

(52) U.S. Cl. 361/748; 324/537

(57) ABSTRACT

A portable electronic device (1) includes an interface (10), a circuit board (200) and an accessory identifying unit (100). The interface includes a plurality of connectors (VBUS, D+, D− and ID). The circuit board includes a plurality of controlling circuits (21, 22, 23 and 24). The accessory identifying unit is electronically connected to the interface and the circuit board, and includes a plurality of detection circuits (11, 12 and 13) corresponding to the connectors and the controlling circuits. Each detection circuit is electronically connected to its corresponding connector and detection circuit.

### BACKGROUND OF THE INVENTION

1. Field of the Invention

The present invention relates to a portable electronic device and a method for identifying accessories connected to the same.

2. Description of Related Art

Nowadays, portable electronic devices such as mobile phones and personal digital assistants (PDAs) are widely used. In use, a portable electronic device is often electronically connected to different accessories, such as a headset, a charger, a universal serial bus (USB) wire, etc. Thus, interfaces for connecting these accessories are installed in the portable electronic devices.

With the development of portable electronic devices, more and more kinds of interfaces are installed in portable electronic devices to connect with accessories having different functions respectively. However, these interfaces may interfere with the miniaturization of the portable electronic devices.

Therefore, a new portable electronic device is desired in order to overcome the above-described shortcomings.

### SUMMARY

A portable electronic device includes an interface, a circuit board and an accessory identifying unit. The interface includes a plurality of connectors. The circuit board includes a plurality of controlling circuits. The accessory identifying unit is electronically connected to the interface and the circuit board, and includes a plurality of detection circuits corresponding to the connectors and the controlling circuits. Each detection circuit is electronically connected to its corresponding connector and detection circuit.

A method for identifying an accessory connected to a portable electronic device, comprising these steps: installing an interface with a plurality of connectors configured to connect accessories; detecting a first connector when an accessory is connected to the interface; and detecting other connectors according to detecting result of the first connector to identify the connected accessory.

Other advantages and novel features will become more apparent from the following detailed description when taken in conjunction with the accompanying drawings.

### BRIEF DESCRIPTION OF THE DRAWINGS

Many aspects of the present portable electronic device can be better understood with reference to the following drawings. The components in the various drawings are not necessarily drawn to scale, the emphasis instead being placed upon clearly illustrating the principles of the present portable electronic device. Moreover, in the drawings, like reference numerals designate corresponding parts throughout the diagrams, in which:

FIG. 1 is a diagram of a portable electronic device, in accordance with a present embodiment; and

FIG. 2 is a diagram of a method in accordance with a present embodiment for identifying accessories connected to the portable electronic device shown in FIG. 1.

### DETAILED DESCRIPTION OF THE INVENTION

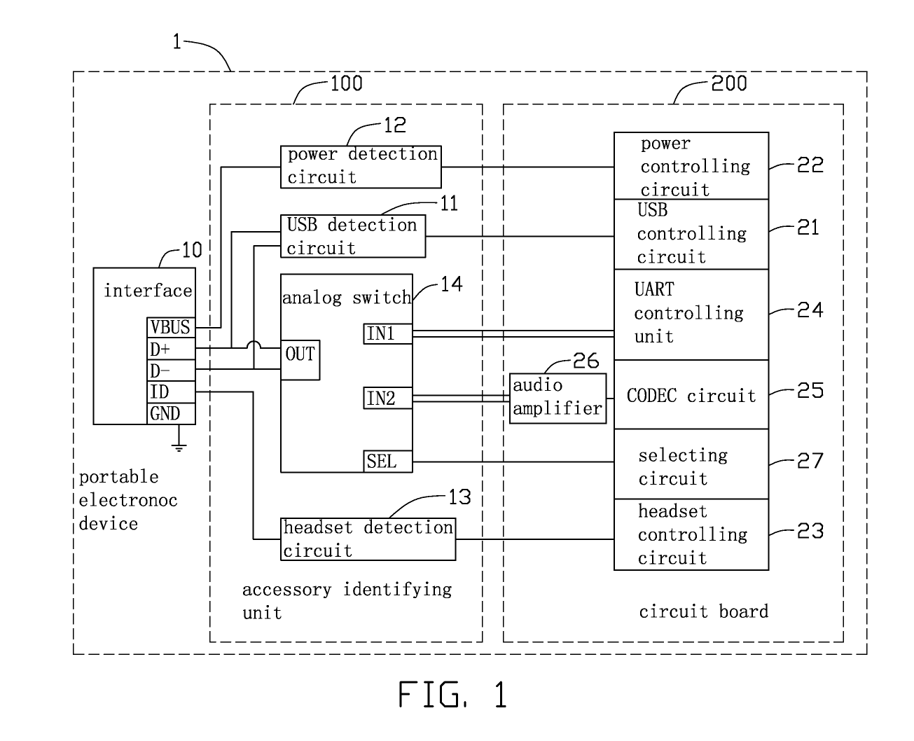

Referring to FIG. 1, a portable electronic device 1 in accordance with a present embodiment is provided. The portable electronic device 1 can be a mobile phone, a laptop, etc. The portable electronic device 1 includes an interface 10 configured to connect different accessories, an accessory identifying unit 100 electronically connected to the interface 10 and a circuit board 200 electronically connected to the accessory identifying unit 100.

The interface 10 is a typical mini-USB interface that including a power connector VBUS configured for supplying electric current the portable electronic device 1, a high potential signal connector D+ and a low potential signal connector D−configured for transferring data, an identify connector ID configured for identifying a state of the portable electronic device 1 or connecting a headset, and a grounding connector GND configured to ground. The interface 10 can be used to connect many types of accessories, such as USB wire, charger, headset, universal asynchronous receiver/transmitter (UART), etc.

The accessory identifying unit 100 includes a USB detection circuit 11, a power detection circuit 12, a headset detection circuit 13 and an analog switch 14 that are all electronically connected to the interface 10. The USB detection circuit 11, the power detection circuit 12 and the headset detection circuit 13 are configured to detect accessories connected to the interface 10. The USB detection circuit 11 is electronically connected to both of the high potential signal connector D+ and the low potential signal connector D−. The power detection circuit 12 is electronically connected to the power connector VBUS. The headset detection circuit 13 is electronically connected to the identity connector ID. The analog switch 14 has two input connectors IN1, IN2, an output connector OUT and a selection connector SEL. The output connector OUT is electronically connected to both of the high potential signal connector D+ and the low potential signal connector D−.

The circuit board 200 includes a USB controlling circuit 21, a power controlling circuit 22, a headset controlling circuit 23 and a UART controlling circuit 24 that are respectively configured for controlling their corresponding accessories. The circuit board 200 further includes a coder-decoder (CODEC) circuit 25, an audio amplifier 26 and a selecting circuit 27.

In fabrication, the USB controlling circuit 21 is electronically connected to the USB detection circuit 11. The power controlling circuit 22 is electronically connected to the power detection circuit 12. The headset controlling circuit 23 is electronically connected to the headset detection circuit 13. The UART controlling circuit 24 is electronically connected to the inner connector IN1 of the analog switch 14. In this way, these controlling circuits are electronically connected to their corresponding detection circuits, and then electronically connected to the interface 10 via the detection circuits or the analog switch 14. When an accessory is connected to the interface 10, it can be controlled to work by its corresponding controlling circuit.

The CODEC circuit 25 is electronically connected to the audio amplifier 26, and the audio amplifier 26 is electronically connected to the inner connector IN2 of the analog switch 14. The selecting circuit 27 is electronically connected to the selection connector SEL. When no accessory is connected to the interface 10, the selecting circuit 27 is turned off. When an accessory is connected to the interface 10, the selecting circuit 27 is turned on.

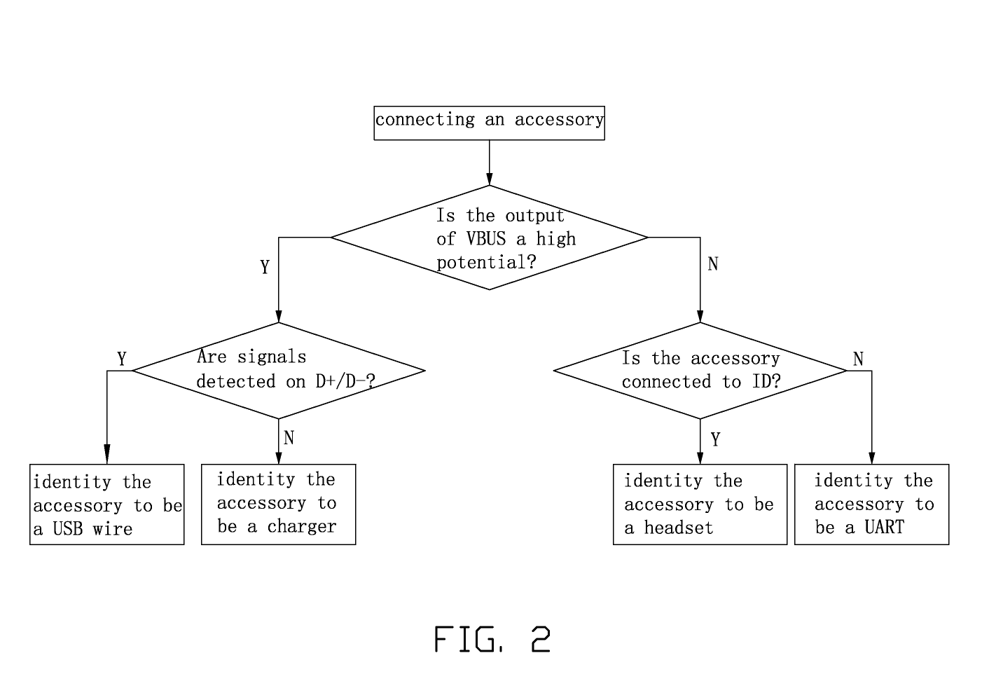

In use, when an accessory is connected to the interface 10, the portable electronic device 1 first detects the type of the accessory, and then cooperates with the connected accessory to function. Also referring to FIG. 2, a method in accordance with a present embodiment that is used to identify accessories connected to the portable electronic device 1 is provided. The method includes these steps as follows.

An aforementioned portable electronic device 1 is provided.

When an accessory is connected to the interface 10 of the portable electronic device 1, the power detection circuit 12 is used to detect the power connector VBUS. It is understandable that the connected accessory can supply electric current the portable electronic device 1 if the detected output of the power connector VBUS has a high electric potential. Besides a charger, a USB wire connected to a computer can also charge a portable electronic device. Thus, the connected accessory can be identified as a charger or a USB wire.

For further identifying the accessory, the USB detection circuit 11 is used to detect the high potential signal connector D+ and the low potential signal connector D−. If signals are detected on the high potential signal connector D+ and the low potential signal connector D−, the connected accessory can supply electric current and transfer USB signals to the portable electronic device 1, thus the accessory is identified as a USB wire. Contrarily, if no signal is detected on the high potential signal connector D+ and the low potential signal connector D−, the connected accessory can supply electric current but cannot transfer USB signals to the portable electronic device 1, thus the accessory is identified as a charger.

It is understandable that the connected accessory cannot supply electric current to the portable electronic device 1 if the detected output of the power connector VBUS is low. For further identifying the accessory, the headset detection circuit 23 is used to detect the identity connector ID. Since the identify connector ID can also be used to connect to a headset, if an accessory connection is detected by the identify connector ID, the accessory is identified as a headset. Contrarily, if no accessory connection is detected by the identify connector ID, the accessory is identified as a UART.

After detection and identification, the portable electronic device 1 cooperates with the connected accessory to function. When an accessory is connected to the interface 10, the analog switch 14 and the selecting circuit 27 are turned on. If the connected accessory is identified as a USB wire, the selection switch circuit 27 sends a selection signal to the selection connector SEL of the analog switch 14 to activate the CODEC circuit 25 and the audio amplifier 26. In this way, the CODEC circuit 25 can be connected to the interface 10 via the audio amplifier 26, thus the connected USB wire can be used to transfer audio signals. If the connected accessory is identified as a UART, the selection switch circuit 27 sends a selection signal to the selection connector SEL of the analog switch 14 to activate the UART controlling circuit 24, then the UART controlling circuit 24 cooperates with the connected UART to transfer data. Understandably, according to the aforementioned identifying method, when no accessory is connected to the interface 10, the portable electronic device 1 may mistakenly identify that a UART is connected to the interface 10. However, when the selecting circuit 27 is turned off, the UART controlling circuit 24 of portable electronic device 1 is prevented from turning on.

Understandably, the identify connector ID can also be used to connect other accessories which unilaterally transfers data, such as microphones. The interface 10 of the portable electronic device 1 can be used to connect many types of accessories, and the type of the connected accessories can be identified via detecting the connectors of the interface 10. Thus, the numbers of interfaces mounted on the portable electronic device 1 is decreased, and the portable electronic device 1 can be further miniaturized.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

1. A portable electronic device, comprising:
an interface for connecting at least two different types of external accessories to the device, the interface including a plurality of connectors, each connector capable of connecting at least two different types of external accessories to the device;
a circuit board including a plurality of controlling circuits; and
an accessory identifying unit electronically connected to the interface and the circuit board, and including a plurality of detection circuits corresponding to the connectors and the controlling circuits; each detection circuit being electronically connected to its corresponding connector and controlling circuit; when an accessory is connected to the interface, the detection circuits detecting the connectors to identify the type of the accessory, and the accessory being controlled to work by its corresponding controlling unit according to identifying result.

2. The portable electronic device as claimed in claim 1, wherein the accessory identifying unit includes an analog switch, the interface includes a high potential signal connector and a low potential signal connector, and the circuit board includes a universal asynchronous receiver/transmitter (UART) controlling circuit; the UART controlling circuit being electronically connected to the high potential signal connector and the low potential signal connector via the analog switch.

3. The portable electronic device as claimed in claim 2, wherein the analog switch includes two input connectors, one output connectors and a selection connector, the circuit board includes a coder/decoder (CODEC) circuit and a selection circuit; the UART controlling circuit and the CODEC circuit being respectively electronically connected to an input connector, the output connector being electronically connected to both of the high potential signal connector and the low potential signal connector, the selection circuit being electronically connected to the selection connector.

4. The portable electronic device as claimed in claim 2, wherein the accessory identifying unit includes a USB detection circuit and the circuit board includes a USB controlling circuit electronically connected to the high potential signal connector and the low potential signal connector via the USB detection circuit.

5. The portable electronic device as claimed in claim 1, wherein the accessory identifying unit includes a power detection circuit, the interface includes a power connector and the circuit board includes a power controlling circuit electronically connected to the power connector via the power detection circuit.

6. The portable electronic device as claimed in claim 1, wherein the accessory identifying unit includes a headset detection circuit, the interface includes an identify connector and the circuit board includes a headset controlling circuit electronically connected to the identify connector via the headset detection circuit.

7. A method for identifying an accessory connected to a portable electronic device, comprising steps:
installing an interface which includes a plurality of connectors for connecting to accessories;
detecting a first connector if an accessory is connected to the interface; and
detecting other connectors according to detected result of the first connector to identify the connected accessory.

8. The method as claimed in claim 7, wherein the step of detecting other connectors according to the detected result of the first connector to identify the connected accessory includes steps:
detecting a second connector and a third connector if the detected output of the first connector is a high potential;
identifying the connected accessory to be a USB wire if signals are detected on the second connector and the third connector; and
identifying the connected accessory to be a charger wire if no signal is detected on the second connector and the third connector.

9. The method as claimed in claim 7, wherein the step of detecting other connectors according to the detected result of the first connector to identify the connected accessory includes steps:
detecting a fourth connector if the detected output of the first connector is a low potential;
identifying the connected accessory to be a headset if an accessory connected to the fourth connector is detected; and
identifying the connected accessory to be a UART if no accessory connected to the fourth connector is detected.

10. The portable electronic device as claimed in claim 1, wherein the accessories connected to the interface is any one of the group consisting of USB wire, charger, headset, and UART.

11. The portable electronic device as claimed in claim 1, wherein the interface includes a power connector, a high potential signal connector, a low potential signal connector and an identify connector.

12. The portable electronic device as claimed in claim 11, wherein the accessory identifying unit includes a power detection circuit, and the circuit board includes a power controlling circuit electronically connected to the power connector via the power detection circuit.

13. The portable electronic device as claimed in claim 12, wherein the accessory Identifying unit includes a USB detection circuit, and the circuit board includes a USB controlling circuit electronically connected to the high potential signal connector and the low potential signal connector via the USB detection circuit.

14. The portable electronic device as claimed in claim 13, wherein an accessory connected to the interface is identified to be a USB wire when the power detection circuit detects a high electric potential on the power connector and the USB detection circuit detects signals on the high potential signal connector and the low potential signal connector.

15. The portable electronic device as claimed in claim 13, wherein an accessory connected to the interface is identified to be a charger when the power detection circuit detects a high electric potential on the power connector and the USB detection circuit detects no signal on the high potential signal connector and the low potential signal connector.

16. The portable electronic device as claimed in claim 12, wherein the accessory identifying unit includes a headset detection circuit and the circuit board includes a headset controlling circuit electronically connected to the identify connector via the headset detection circuit.

17. The portable electronic device as claimed in claim 16, wherein an accessory connected to the interface is identified to he a headset when the power detection circuit detects a low electric potential on the power connector and the headset detection circuit detects an accessory connection on the identify connector.

18. The portable electronic device as claimed in claim 16, wherein an accessory connected to the interface is identified to be a UART when the power detection circuit detects a low electric potential on the power connector and the headset detection circuit detects no accessory connection on the identify connector.

19. The portable electronic device as claimed in claim 18, wherein the accessory identifying unit includes an analog switch connected to the interface for preventing the portable electronic device from activating its UART function when no accessory connected to the interface.
